(19) United States
(12) Patent Application Publication
(10) Pub. No.: US 2010/0187590 A1
(43) Pub. Date: Jul. 29, 2010

(54) Semiconductor device including metal insulator semiconductor transistor

(75) Inventor: Hirokazu Ishigaki, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/656,261

(22) Filed: Jan. 22, 2010

(30) Foreign Application Priority Data
Jan. 26, 2009 (JP) 14727/2009

(51) Int. Cl. H01L 29/788

(52) U.S. Cl. 257/314; 257/E29.3

(57) ABSTRACT

A semiconductor device includes a plurality of metal insulator semiconductor (MIS) transistors. The plurality of MIS transistors each includes a gate electrode formed above a channel region of a semiconductor substrate via a gate insulating film and source/drain regions formed on both sides of the channel region. The gate electrode is electrically connected to an interconnect via a first plug. The interconnect has a plurality of vias formed thereon. The plurality of MIS transistors have threshold voltages different from one another due to variations in quantities of electric charges trapped by the gate insulating films respectively corresponding to the plurality of MIS transistors.

### INCORPORATION BY REFERENCE

This application is based upon and claims the benefit of priority from Japanese Patent Application No. 2009-014727 which was filed on Jan. 26, 2009, the disclosure of which is incorporated herein in its entirety by reference.

### BACKGROUND OF THE INVENTION

1. Field of the Invention

The present invention relates to a semiconductor device including a metal insulator semiconductor (MIS) transistor that serves as a power supply switch of a functional block, and more particularly, to a semiconductor device including a plurality of types of MIS transistors having different threshold voltages.

2. Description of Related Art

In the field of semiconductor devices, reduction in electric power consumption in a semiconductor integrated circuit has been an important issue. There is known a conventional semiconductor integrated circuit in which a total leakage current including a sub-threshold leakage current and a substrate current is reduced during a standby mode to reduce electric power consumption during the standby mode (see JP 2008-85571 A; hereinafter, referred to as Patent Document 1). The “sub-threshold leakage current” refers to a leakage current that flows between a source and a drain when a MIS transistor is in an off-state. Examples of the substrate current that flows during the standby mode include a junction leakage current, a gate induced drain leakage (GIDL) current, and the like. The “junction leakage current” refers to a current that flows when a reverse bias is applied to a pn junction. The “GIDL current” refers to a current that flows from a drain to a substrate due to an influence of a gate potential exerted on the edge of the drain below a gate electrode.

Patent Document 1 discloses a semiconductor integrated circuit which includes: a plurality of types of MIS transistors that are provided in an internal circuit and have the same conductivity type and different threshold voltages; and a power supply switch transistor that is provided in the internal circuit and cuts off electric power supply to a functional block during the standby mode, in which the power supply switch transistor is a MIS transistor other than a MIS transistor having the highest threshold voltage among the plurality of types of MIS transistors. According to Patent Document 1, channel impurity concentrations are varied among the plurality of types of MIS transistors. As a result, the plurality of types of MIS transistors have the threshold voltages different from one another.

### SUMMARY

However, the present inventor has recognized the following point. Namely, as the related technology described above, in the case where the channel impurity concentrations are varied among the plurality of types of MIS transistors, the number of photoresists and the number of steps of ion implantation are increased, which leads to an increase in manufacturing cost. Further, for the MIS transistor having a high threshold voltage, it is necessary to set the channel impurity concentration thereof to a high level, and hence the substrate current is increased, which causes an increase in leakage current. When the substrate current is increased, there is a fear that deterioration due to hot carriers or the like may occur.

It is a primary object of the present invention to provide a semiconductor device that is capable of reducing a leakage current without increasing the number of photoresists and the number of steps of ion implantation for manufacturing a plurality of types of MIS transistors having different threshold voltages, even when the threshold voltages are set to high values.

The present invention seeks to solve one or more of the above problems, or to improve upon those problems at least in part.

In one exemplary embodiment, a semiconductor device includes a plurality of metal insulator semiconductor (MIS) transistors. The MIS transistor includes a gate electrode formed above a channel region of a semiconductor substrate via agate insulating film, and source/drain regions formed on both sides of the channel region. The gate electrode is electrically connected to an interconnect via a first plug. The interconnect has a plurality of vias formed thereon. The plurality of MIS transistors have threshold voltages different from one another due to variations in quantities of electric charges trapped by the gate insulating films respectively corresponding to the plurality of MIS transistors.

According to the present invention, an antenna ratio (via area/gate area) is changed, to thereby realize the plurality of types of threshold voltages. Therefore, it is unnecessary to change the impurity concentrations of the channel regions of the MIS transistors, which eliminates the need to increase the number of photoresists and the number of steps of ion implantation. Accordingly, the manufacturing cost of the semiconductor device may be reduced. Further, the antenna ratio maybe set correspondingly to a layout pattern, and interconnect vias and electric charge capturing vias may be formed simultaneously. Therefore, the formation of the electric charge capturing vias does not increase manufacturing steps. Moreover, the threshold voltages are controlled without changing the impurity concentrations of the channel regions, and hence a leakage current including a substrate current and a sub-threshold leakage current may be reduced even when the threshold voltages are set to high values. As a result, the deterioration due to hot carriers may be improved.

### BRIEF DESCRIPTION OF THE DRAWINGS

The above and other purposes, advantages and features of the present invention will become more apparent from the following description of a certain exemplary embodiment taken in conjunction with the accompanying drawings in which:

FIG. 1 is a cross sectional view schematically illustrating a part of a structure of a semiconductor device according to a first exemplary embodiment of the present invention;

FIGS. 2A to 2C are first cross sectional views schematically illustrating steps in a method of manufacturing the semiconductor device according to the first exemplary embodiment of the present invention;

FIGS. 3A and 3B are second cross sectional views schematically illustrating steps in the method of manufacturing the semiconductor device according to the first exemplary embodiment of the present invention;

FIG. 4 is a graph illustrating a dependence on an antenna ratio, of a threshold voltage of a MIS transistor that is not diode-connected in the semiconductor device according to the first exemplary embodiment of the present invention;

FIG. 5 is a graph illustrating a dependence on an antenna ratio, of a threshold voltage of a MIS transistor that is diode-connected in the semiconductor device according to the first exemplary embodiment of the present invention; and

FIG. 6 is a graph illustrating a dependence on a threshold voltage, of a substrate current of a MIS transistor in each of semiconductor devices according to the first exemplary embodiment of the present invention and a comparative example.

### DETAILED DESCRIPTION OF THE EXEMPLARY EMBODIMENTS

The invention will now be described herein with reference to an illustrative exemplary embodiment. Those skilled in the art will recognize that many alternative embodiments can be accomplished using the knowledge of the present invention, and that the invention is not limited to the exemplary embodiment illustrated for explanatory purposes.

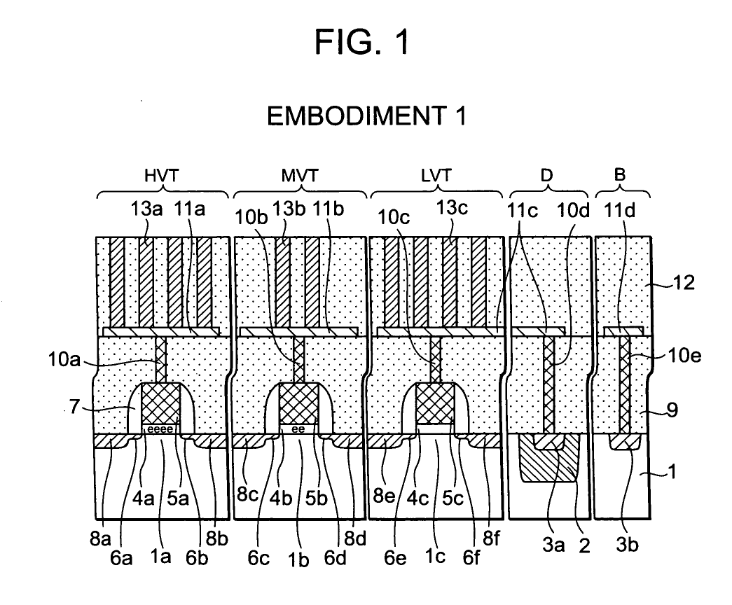

A semiconductor device according to the present invention includes a plurality of metal insulator semiconductor (MIS) transistors (HVT and MVT of FIG. 1), which respectively include: gate electrodes (5a and 5b of FIG. 1) formed above channel regions (1a and 1b of FIG. 1) of a semiconductor substrate (1 of FIG. 1) via gate insulating films (4a and 4b of FIG. 1); and source/drain regions (8a and 8b, and 8c and 8d of FIG. 1) formed on both sides of the channel regions (1a and 1b of FIG. 1), in which the gate electrodes (5a and 5b of FIG. 1) are electrically connected to interconnects (11a and 11b of FIG. 1) via plugs (10a and 10b of FIG. 1), respectively, a plurality of vias (13a and 13b of FIG. 1) are formed on the interconnects (11a and 11b of FIG. 1), respectively, and the plurality of MIS transistors (HVT and MVT of FIG. 1) have threshold voltages different from one another due to variations in quantities of electric charges trapped by the corresponding gate insulating films (4a and 4b of FIG. 1).

Further, the quantities of the electric charges to be trapped by the gate insulating films respectively corresponding to the plurality of MIS transistors may preferably be different from one another according to antenna ratios that are each based on a ratio of an area of the corresponding plurality of vias to an area of the corresponding gate electrode.

Further, each of the antenna ratios may preferably be adjusted by changing one of a number of the plurality of vias and the area of the plurality of vias, with respect to the area of the gate electrode.

Further, the plurality of MIS transistors may preferably have the same conductivity type.

Further, the channel regions of the plurality of MIS transistors may preferably have the same impurity concentration.

Further, the plurality of vias include a first via which may preferably be connected to an interconnect formed in an upper layer, and the plurality of vias include a second via which may preferably avoid connection to the interconnect formed in the upper layer.

Further, the interconnect corresponding to a MIS transistor having a lowest threshold voltage of the plurality of MIS transistors may preferably be diode-connected to the semiconductor substrate via a second plug.

Further, the gate insulating film may trap the electric charges which have been generated during one of formation of the plurality of vias and formation of prepared holes for the plurality of vias.

### First Exemplary Embodiment

FIG. 1 is a cross sectional view schematically illustrating apart of a structure of the semiconductor device according to a first exemplary embodiment of the present invention.

The semiconductor device of FIG. 1 is a semiconductor device including a MIS transistor that serves as a power supply switch of a functional block, and includes a plurality of types (three types) of MIS transistors (HVT, MVT, and LVT) having the same conductivity type and different threshold voltages. The HVT is a MIS transistor having a high threshold voltage. The MVT is a MIS transistor having a middle threshold voltage. The LVT is a MIS transistor having a low threshold voltage. The semiconductor device includes a diode terminal D for diode-connecting a gate electrode 5c of the LVT and a semiconductor substrate 1. The semiconductor device includes a back gate terminal B for controlling a voltage (substrate voltage) of the semiconductor substrate 1. The semiconductor device includes a multilayer interconnect layer on the semiconductor substrate 1 having the HVT, the MVT, the LVT, the diode terminal D, and the back gate terminal B formed thereon.

The HVT as the MIS transistor has the following structure. A gate electrode 5a (for example, polysilicon) is formed above a channel region 1a of the semiconductor substrate 1 (for example, p-type silicon substrate) via a gate insulating film 4a (for example, silicon oxide film or ONO film). Source/drain regions 8a and 8b (for example, n⁺-type impurity diffusion regions) are formed on both sides of the channel region 1a of the semiconductor substrate 1. Side walls 7 (for example, silicon oxide films) are formed of an insulating material on both sides of the gate electrode 5a. Extension regions 6a and 6b (for example, n⁺-type impurity diffusion regions) having a depth smaller than those of the source/drain regions 8a and 8b are formed below the side walls 7 in the semiconductor substrate 1. The source/drain region 8a is connected to the extension region 6a while the source/drain region 8b is connected to the extension region 6b. The gate electrode 5a is electrically connected to a control circuit (not shown) via a plug 10a and an interconnect 11a. It should be noted that the gate electrode 5a is not diode-connected. The source/drain region 8a is electrically connected to a power supply line (not shown). The power supply line may be a ground line. The source/drain region 8b is electrically connected to a functional block (not shown). The gate insulating film 4a traps more electric charges than gate insulating films 4b and 4c. The film thickness of the gate insulating film 4a is the same as those of the gate insulating films 4b and 4c and is set according to a material to be used, a target quantity of electric charges to be trapped, and the like.

The MVT as the MIS transistor has the following structure. A gate electrode 5b (for example, polysilicon) is formed above a channel region 1b of the semiconductor substrate 1 (for example, p-type silicon substrate) via a gate insulating film 4b (for example, silicon oxide film or ONO film). Source/drain regions 8c and 8d (for example, n⁺-type impurity diffusion regions) are formed on both sides of the channel region 1b of the semiconductor substrate 1. Side walls 7 (for example, silicon oxide films) are formed of an insulating material on both sides of the gate electrode 5b. Extension regions 6c and 6d (for example, n⁺-type impurity diffusion regions) having a depth smaller than those of the source/drain regions 8c and 8d are formed below the side walls 7 in the semiconductor substrate 1. The source/drain region 8c is connected to the extension region 6c while the source/drain region 8d is connected to the extension region 6d. The gate electrode 5b is electrically connected to a control circuit (not shown) via a plug 10b and an interconnect 11b. It should be noted that the gate electrode 5b is not diode-connected. The source/drain region 8c is electrically connected to the power supply line (not shown). The power supply line may be a ground line. The source/drain region 8c is electrically connected to a functional block (not shown). The gate insulating film 4b traps less electric charges than the gate insulating film 4a and more electric charges than the gate insulating film 4c. The film thickness of the gate insulating film 4b is the same as those of the gate insulating films 4a and 4c and is set according to a material to be used, a target quantity of electric charges to be trapped, and the like.

The LVT as the MIS transistor has the following structure. The gate electrode 5c (for example, polysilicon) is formed above a channel region 1c of the semiconductor substrate 1 (for example, p-type silicon substrate) via the gate insulating film 4c (for example, silicon oxide film or ONO film). Source/drain regions 8e and 8f (for example, n⁺-type impurity diffusion regions) are formed on both sides of the channel region 1c of the semiconductor substrate 1. The side walls 7 (for example, silicon oxide films) are formed of an insulating material on both sides of the gate electrode 5c. Extension regions 6e and 6f (for example, n⁺-type impurity diffusion regions) having a depth smaller than those of the source/drain regions 8e and 8f are formed below the side walls 7 in the semiconductor substrate 1. The source/drain region 8e is connected to the extension region 6e while the source/drain region 8f is connected to the extension region 6f. The gate electrode 5c is electrically connected to a control circuit (not shown) via a plug 10c and an interconnect 11c, and is electrically connected also to the diode terminal D via the plug 10c, the interconnect 11c, and an interconnect 11d. The source/drain region 8e is electrically connected to the power supply line (not shown). The power supply line may be the ground line. The source/drain region 8f is electrically connected to the functional block (not shown). The gate insulating film 4c traps no electric charge. This is because electric charges captured by vias 13c flow toward the diode terminal D side rather than toward the gate electrode 5c side.

In the diode terminal D, a well 2 (for example, n⁺-type impurity diffusion region) having a conductivity type opposite to that of the semiconductor substrate 1 (for example, p-type silicon substrate) is formed in the semiconductor substrate 1, and an impurity diffusion region 3a (for example, p⁺-type impurity diffusion region) having the same conductivity type as that of the semiconductor substrate 1 (opposite to that of the well 2) and a high impurity concentration is formed in the well 2. The impurity diffusion region 3a is electrically connected to the gate electrode 5c of the LVT via a plug 10d, the interconnect 11c, and the plug 10c, and is electrically connected also to the control circuit (not shown) via the plug 10d and the interconnect 11c. The diode terminal D functions such that the electric charges captured by the vias 13c are caused to flow into the semiconductor substrate 1 so as not to be trapped by the gate insulating film 4c.

In the back gate terminal B, an impurity diffusion region 3b (for example, p⁺-type impurity diffusion region) having the same conductivity type as that of the semiconductor substrate 1 (for example, p-type silicon substrate) and a high impurity concentration is formed in the semiconductor substrate 1. The impurity diffusion region 3b is electrically connected to the control circuit (not shown) via a plug 10e and the interconnect 11d. The back gate terminal B serves to control a voltage (back gate voltage) of the semiconductor substrate 1.

The multilayer interconnect layer has the following structure. An interlayer insulting film 9 (for example, silicon oxide film) is formed on the semiconductor substrate 1 having the HVT, the MVT, the LVT, the diode terminal D, and the back gate terminal B formed thereon. The plugs 10a to 10e (for example, tungsten) are filled into prepared holes formed in the interlayer insulating film 9. The interconnects 11a to 11d (for example, copper) are formed on the interlayer insulating film 9. An interlayer insulating film 12 (for example, silicon oxide film) is formed on the interconnects 11a to 11d and the interlayer insulating film 9. The vias 13a to 13c (for example, copper) are filled into prepared holes formed in the interlayer insulating film 12. It should be noted that, though not illustrated, the multilayer interconnect layer further includes other interlayer insulating films, vias, and interconnects on the interlayer insulating film 12.

The plug 10a is electrically connected to the gate electrode 5a of the HVT and the interconnect 11a. The plug 10b is electrically connected to the gate electrode 5b of the MVT and the interconnect 11b. The plug 10c is electrically connected to the gate electrode 5c of the LVT and the interconnect 11c. The plug 10d is electrically connected to the impurity diffusion region 3a of the diode terminal D and the interconnect 11c. The plug 10e is electrically connected to the impurity diffusion region 3b of the back gate terminal B and the interconnect 11d.

The interconnect 11a is electrically connected to the gate electrode 5a of the HVT via the plug 10a, is electrically connected to the plurality of vias 13a corresponding to the HVT, and is electrically connected to the control circuit (not shown). The interconnect 11b is electrically connected to the gate electrode 5b of the MVT via the plug 10b, is electrically connected to the plurality of vias 13b corresponding to the MVT, and is electrically connected to the control circuit (not shown). The interconnect 11c is electrically connected to the gate electrode 5c of the LVT via the plug 10c, is electrically connected to the impurity diffusion region 3a of the diode terminal D via the plug 10d, is electrically connected to the plurality of vias 13c corresponding to the LVT, and is electrically connected to the control circuit (not shown). The interconnect 11d is electrically connected to the impurity diffusion region 3b of the back gate terminal B via the plug 10e, and is electrically connected to the control circuit (not shown).

The vias 13a are electric charge capturing vias that correspond to the HVT and are formed on the interconnect 11a, and are electrically connected to the interconnect 11a. The electric charges captured by the vias 13a are supplied to the gate insulating film 4a via the interconnect 11a, the plug 10a, and the gate electrode 5a, and then trapped by the gate insulating film 4a. The vias 13b are electric charge capturing vias that correspond to the MVT and are formed on the interconnect 11b, and are electrically connected to the interconnect 11b. The electric charges captured by the vias 13b are supplied to the gate insulating film 4b via the interconnect 11b, the plug 10b, and the gate electrode 5b, and then trapped by the gate insulating film 4b. The vias 13c are electric charge capturing vias that correspond to the LVT and are formed on the interconnect 11c, and are electrically connected to the interconnect 11c. The electric charges captured by the vias 13c flow into the semiconductor substrate 1 via the interconnect 11c, the plug 10d, the impurity diffusion region 3a of the diode terminal D, and the well 2. The number or base area of the vias 13a corresponding to the HVT are set to be larger (or wider) than the number or base area of the vias 13b corresponding to the MVT, in order to increase the quantity of the electric charges that may be captured by the vias 13a. It should be noted that the number or base area of the vias 13c corresponding to the LVT is not particularly limited because the vias 13c are electrically connected to the semiconductor substrate 1 via the interconnect 11c, the plug 10d, the impurity diffusion region 3a of the diode terminal D, and the well 2. The vias 13a to 13c include two types of vias, that is, interconnect vias and electric charge capturing vias. The interconnect vias provide electrical connection to an interconnect formed in an upper layer, and in addition, has a function of capturing electric charges. On the other hand, the electric charge capturing vias exclusively serve to capture electric charges, and thus are not electrically connected to the interconnect formed in the upper layer. It should be noted that the vias 13c may include no electric charge capturing via.

In a case where the HVT, the MVT, and the LVT are NMOS transistors, the semiconductor substrate 1, the impurity diffusion region 3a, and the impurity diffusion region 3b are set to be the p-type whereas the source/drain regions 8a to 8f and the well 2 are set to be the n-type. On the other hand, in a case where the HVT, the MVT, and the LVT are PMOS transistors, the semiconductor substrate 1, the impurity diffusion region 3a, and the impurity diffusion region 3b are set to be the n-type whereas the source/drain regions 8a to 8f and the well 2 are set to be the p-type.

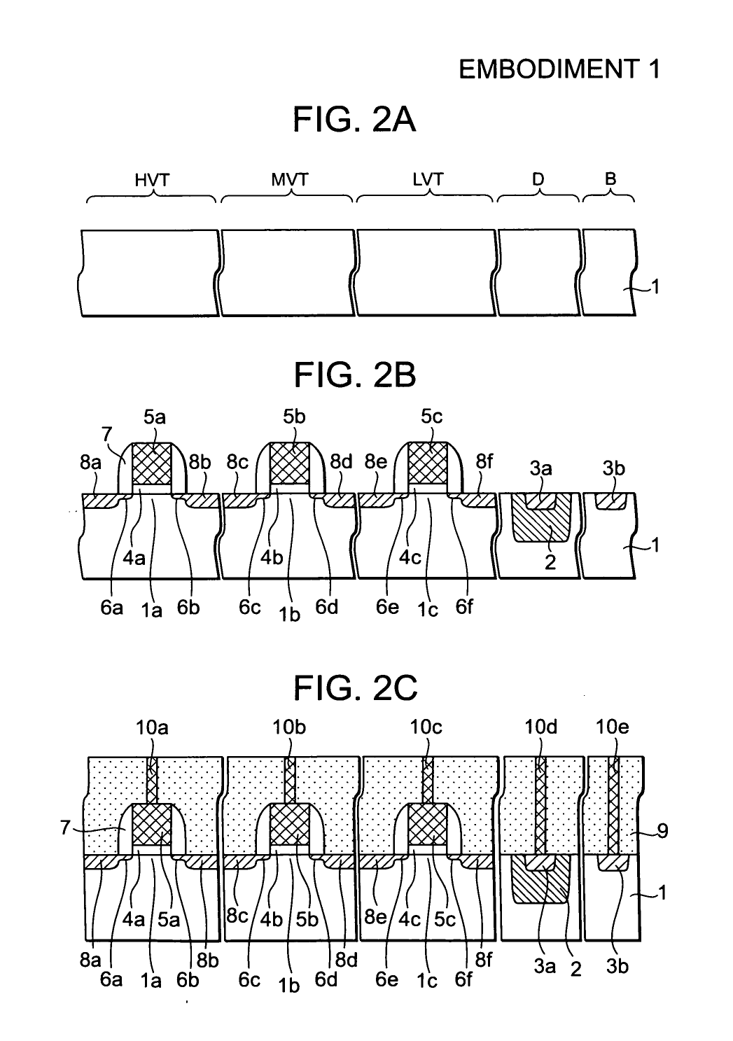

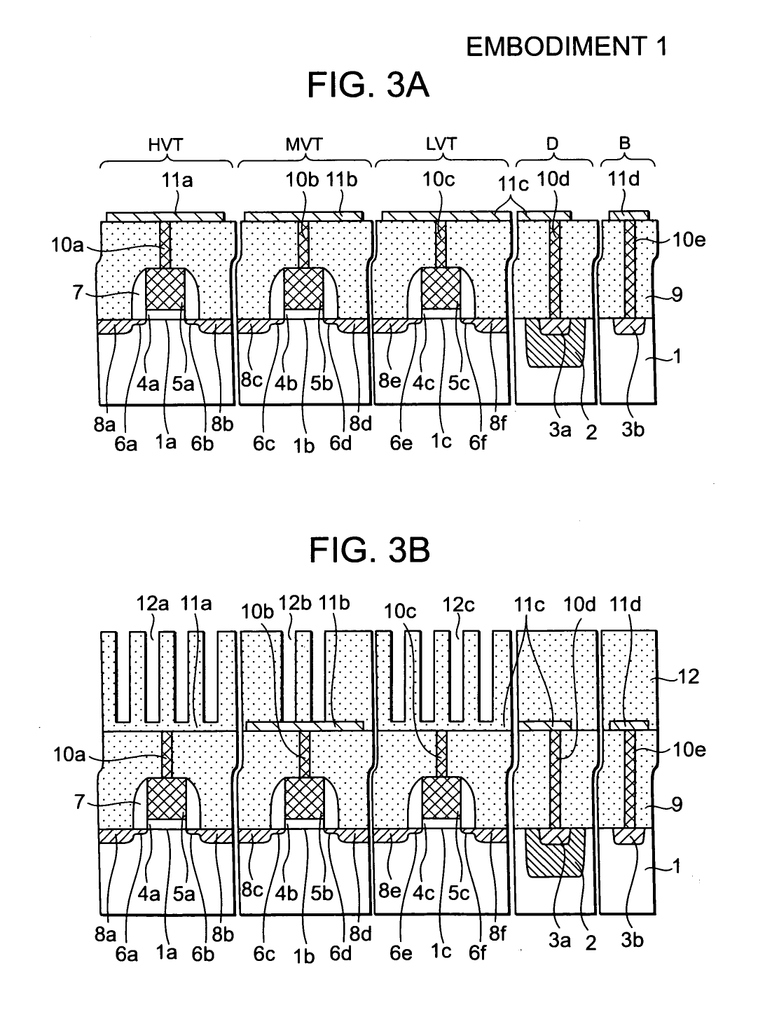

Next, a method of manufacturing the semiconductor device according to the first exemplary embodiment of the present invention is described with reference to the drawings. FIGS. 2A to 2C and 3A and 3B are cross sectional views schematically illustrating steps in the method of manufacturing the semiconductor device according to the first exemplary embodiment of the present invention.

First, p-type impurities are injected and diffused in the semiconductor substrate 1 (for example, p-type silicon substrate) such that portions corresponding to the channel regions 1a, 1b, and 1c of the respective plurality of types of MIS transistors (HVT, MVT, and LVT) have the same impurity concentration (see FIG. 2A). It should be noted that, if the semiconductor substrate 1 has a predetermined level of impurity concentration, the injection and diffusion of the p-type impurities into the portions corresponding to the channel regions 1a, 1b, and 1c may be omitted. In this step, a photoresist is formed at most once.

Next, the well 2 is formed in a connection region of the diode terminal D in the semiconductor substrate 1. Then, the impurity diffusion region 3a is formed in the well 2, and the impurity diffusion region 3b is formed in a connection region of the back gate terminal B in the semiconductor substrate 1. Then, the gate electrodes 5a, 5b, and 5c are formed above the channel regions 1a, 1b, and 1c via the gate insulating films 4a, 4b, and 4c. Then, the extension regions 6a and 6b, 6c and 6d, and 6e and 6f are formed on the both sides of the channel regions 1a, 1b, and 1c, respectively, in the semiconductor substrate 1. Then, the side walls 7 are formed on the both sides of the gate electrodes 5a, 5b, and 5c. Then, the source/drain regions 8a and 8b, 8c and 8d, and 8e and 8f having a depth larger than those of the extension regions 6a to 6f are formed on the both sides of the channel regions 1a, 1b, and 1c, respectively (see FIG. 2B).

Next, the interlayer insulting film 9 is formed on the semiconductor substrate 1 having the HVT, the MVT, the LVT, the diode terminal D, and the back gate terminal B formed thereon. After that, the prepared holes for the plugs 10a to 10e are formed. Then, the plugs 10a to 10e are filled into the prepared holes formed in the interlayer insulting film 9 (see FIG. 2C).

Next, the interconnects 11a to 11d are formed on the interlayer insulating film 9 including the plugs 10a to 10e (see FIG. 3A). It should be noted that the interconnects 11a and 11b are not diode-connected to the semiconductor substrate 1. The interconnect 11c is formed also in the connection region of the diode terminal D, and thus is diode-connected to the semiconductor substrate 1.

Next, the interlayer insulating film 12 is formed on the interconnects 11a to 11d and the interlayer insulating film 9. After that, prepared holes 12a, 12b, and 12c for the vias (including electric charge capturing vias and interconnect vias) are formed in the interlayer insulating film 12 (see FIG. 3B). In forming the prepared holes, a photoresist is formed on the interlayer insulating film 12, and reactive ion etching is performed with the photoresist being used as a mask, to thereby form the prepared holes. In forming the photoresist, patterning is performed so as to form a predetermined number of opening portions or to form opening portions having a predetermined area, according to threshold voltages to be set for the MIS transistors (HVT, MVT, and LVT). The reactive ion etching is performed by placing the wafer in plasma. In the case of the reactive ion etching, electric charges enter from parts of the interconnects 11a and 11b exposed at the prepared holes. The electric charges that have entered the interconnects 11a and 11b pass through the plugs 10a and 10b and the gate electrodes 5a and 5b, and then are trapped by the gate insulating films 4a and 4b. The area of the part of the interconnect 11a exposed at the prepared holes is larger than the area of the part of the interconnect 11b exposed at the prepared holes. Therefore, the quantity of the electric charges trapped by the gate insulating film 4a is larger than the quantity of the electric charges trapped by the gate insulating film 4b. Accordingly, the threshold voltages of the MIS transistors may be controlled. It should be noted that the prepared holes include both kinds of prepared holes, that is, prepared holes for the interconnect vias and prepared holes for the electric charge capturing vias.

Next, the vias 13a, 13b, and 13c are filled into the prepared holes 12a, 12b, and 12c formed in the interlayer insulating film 12, respectively (see FIG. 1). After that, the interlayer insulating film (not shown), the vias (not shown), and the interconnects (not shown) are to be formed on the interlayer insulating film 12 including the vias 13a, 13b, and 13c. The vias 13a, 13b, and 13c are formed in the following manner. A barrier metal film (not shown) is formed by a plasma CVD process on the interlayer insulating film 12 including the prepared holes 12a, 12b, and 12c. A metal seed layer (not shown) is formed by a sputtering process. A copper plating layer is formed by a plating process. After that, chemical mechanical polishing (CMP) is performed. The steps such as the plasma CVD process and the sputtering process are performed on the wafer placed in plasma. Electric charges are generated in the steps such as the plasma CVD process and the sputtering process. The generated electric charges pass through the interconnects 11a and 11b, the plugs 10a and 10b, and the gate electrodes 5a and 5b, and then are trapped by the gate insulating film 4a and 4b. The area of the plug 10a is larger than the area of the plug 10b. Therefore, the quantity of the electric charges trapped by the gate insulating film 4a is larger than the quantity of the electric charges trapped by the gate insulating film 4b. Accordingly, the threshold voltages of the MIS transistors may be controlled. It should be noted that, in the LVT in which the gate electrode 5c is diode-connected to the semiconductor substrate 1, the electric charges escape into the semiconductor substrate 1 via the interconnect 11c, the plug 10d, the impurity diffusion region 3a, and, the well 2.

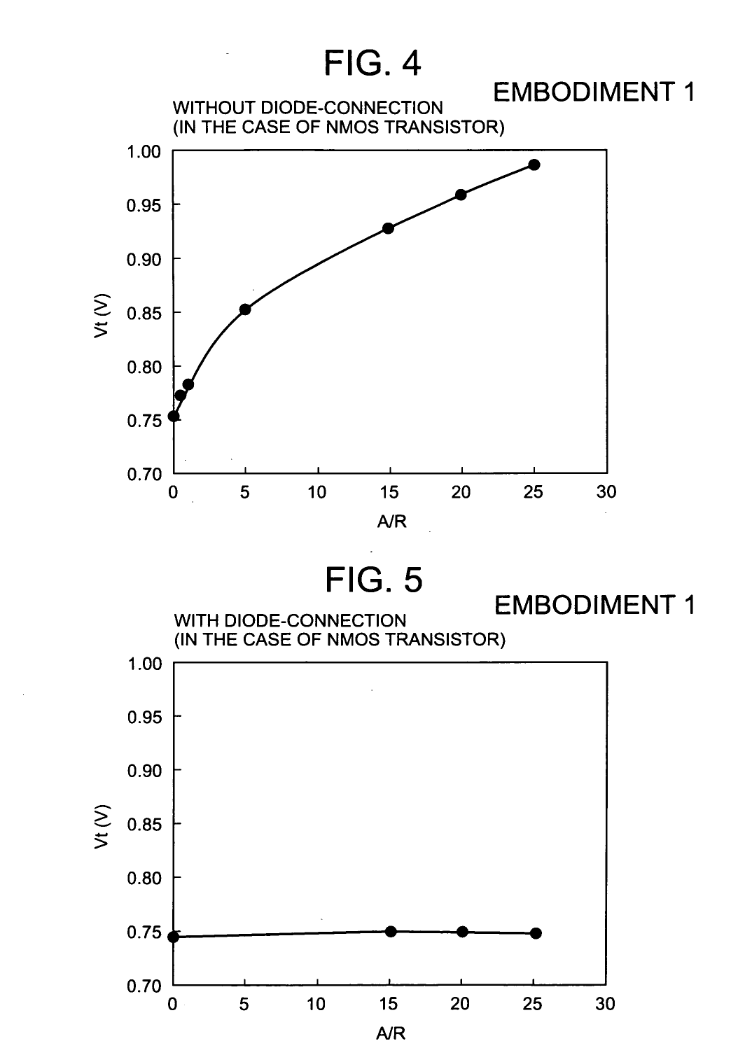

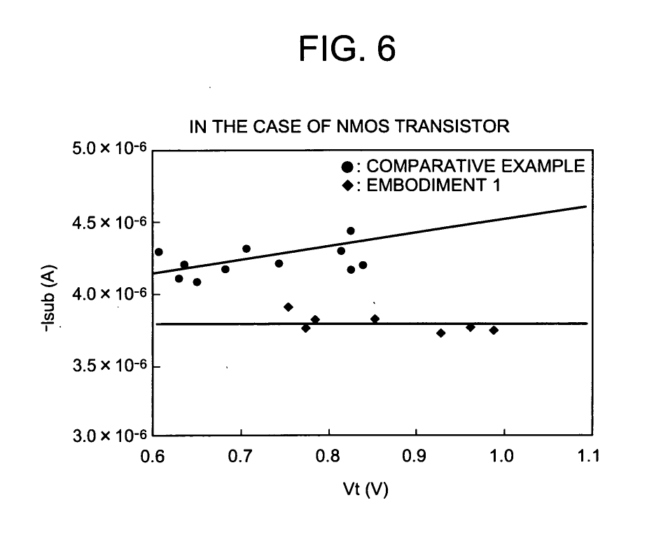

Next, an operation of the semiconductor device according to the first exemplary embodiment of the present invention is described with reference to the drawings. FIG. 4 is a graph illustrating a dependence on an antenna ratio, of a threshold voltage of a MIS transistor that is not diode-connected in the semiconductor device according to the first exemplary embodiment of the present invention. FIG. 5 is a graph illustrating a dependence on an antenna ratio, of a threshold voltage of a MIS transistor that is diode-connected in the semiconductor device according to the first exemplary embodiment of the present invention. FIG. 6 is a graph illustrating a dependence on a threshold voltage, of a substrate current of a MIS transistor in each of semiconductor devices according to the first exemplary embodiment of the present invention and a comparative example.

In the first exemplary embodiment, respective threshold voltages Vt of the MIS transistors are controlled mainly by adjusting the quantities of the electric charges trapped by the gate insulating films 4a, 4b, and 4c. The threshold voltage Vt becomes higher as the quantity of the electric charges increases. Conversely, the threshold voltage Vt becomes lower as the quantity of the electric charges reduces. Therefore, the quantities of the electric charges trapped by the respective gate insulating films 4a, 4b, and 4c of the plurality of types of MIS transistors (HVT, MVT, and LVT) are different from one another. The quantity of the electric charges trapped by the gate insulating film 4a of the HVT having a high threshold voltage is larger than the quantity of the electric charges trapped by the gate insulating film 4b of the MVT having a middle threshold voltage. The quantity of the electric charges trapped by the gate insulating film 4b of the MVT having a middle threshold voltage is larger than the quantity of the electric charges trapped by the gate insulating film 4c of the LVT having a low threshold voltage. Other parameters are the same among the plurality of types of MIS transistors (HVT, MVT, and LVT). For example, the film thicknesses and base areas of the gate electrodes 5a, 5b, and 5c, the film thicknesses of the gate insulating films 4a, 4b, and 4c, and the impurity concentrations of the channel regions 1a, 1b, and 1c in the respective plurality of types of MIS transistors (HVT, MVT, and LVT) are the same.

The quantity of the electric charges trapped by the gate insulating film 4a or 4b corresponding to the gate electrode 5a or 5b that is not diode-connected may be controlled according to a ratio (antenna ratio (A/R)) of the area (base area A) of the vias 13a or 13b to the area (base area R) of the gate electrode 5a or 5b. Therefore, the threshold voltages Vt of the MIS transistors (HVT and MVT) depend on the antenna ratio (A/R), and become higher as the antenna ratio increases and become lower as the antenna ratio decreases. The base areas R of the vias 13a and 13b may be controlled mainly by the numbers of the vias 13a and 13b, respectively. Electric charges generated during the formation of the vias or the prepared holes for the vias are mainly used as the electric charges to be trapped by the gate insulating films 4a and 4b.

On the other hand, with regard to the threshold voltage of the LVT having the gate electrode 5c that is diode-connected, the electric charges escape into the semiconductor substrate 1, and hence the electric charges are not trapped by the gate insulating film 4c even when the antenna ratio (A/R) is high. As a result, the threshold voltage remains low without change (see FIG. 5).

The electric charges generated during the formation of the vias or the prepared holes for the vias are mainly used as the electric charges trapped by the gate insulating films 4a and 4b. Cu is used for forming the vias 13a, 13b, and 13c on the interconnects 11a to 11d. It is difficult to process Cu by dry etching, and hence the CMP is employed. The CMP may include a step in which Cu is exposed to a wet atmosphere, for example, when the CMP is performed in the wet atmosphere or cleaning after the CMP is performed in the wet atmosphere. A stable oxide film cannot be formed on a surface of the metal of Cu, and hence Cu is always susceptible to moisture and easily charged. Meanwhile, a step of using plasma is performed as a process method other than the steps performed in the wet atmosphere. Electric charges exist in plasma, and hence the electric charges enter from a conductive portion exposed on a wafer surface, pass through the vias 13a and 13b, the interconnects 11a and 11b, the plugs 10a and 10b, and the gate electrodes 5a and 5b, to be trapped by the gate insulating films 4a and 4b. Further, steps such as the reactive ion etching during the formation of the prepared holes, the plasma CVD process during the formation of the barrier metal film, the sputtering process of the metal seed layer before the formation of the metal films for the vias are performed by placing the wafer in plasma. The electric charges existing in plasma enter from the conductive portion exposed on the wafer surface, pass through the interconnects 11a and 11b, the plugs 10a and 10b, and the gate electrodes 5a and 5b, and then are trapped by the gate insulating films 4a and 4b. With regard to the vias 13a and 13b and the prepared holes therefor, it is noteworthy that side wall components thereof are larger than those of the interconnects 11a and 11b and thus the areas thereof exposed to plasma are larger, which contributes to satisfactorily capture the electric charges.

In a case where the MIS transistors of the semiconductor device according to the first exemplary embodiment are an NMOS type, during a standby mode, a source potential (corresponding to a potential of each of the source/drain regions 8a, 8c, and 8e) is 0 V, a gate potential (corresponding to a potential of each of the gate electrodes 5a, 5b, and 5c) is 0 V, a drain potential (corresponding to a potential of each of the source/drain regions 8b, 8d, and 8f) is substantially a power supply potential VDD, and a substrate potential (corresponding to a potential of the semiconductor substrate 1) is set to be a value smaller than 0 V. During the standby mode, a sub-threshold leakage current Isubth and a substrate current Isub flow between the source/drain regions. The sub-threshold leakage current Isubth tends to decrease as the threshold voltage Vt becomes higher. The substrate current Isub tends to increase as the impurity concentration of the channel region becomes higher and increase as a control amount of a substrate potential Vsub becomes larger while the threshold voltage tends to become higher.

In the case of the related art (Patent Document 1 as the comparative example), the impurity concentrations of the channel regions are changed, to thereby realize the plurality of types of threshold voltages. Therefore, the impurity concentration of the channel region of the MIS transistor having a high threshold voltage is high, and the substrate current Isub increases (see the comparative example of FIG. 6). Further, when the substrate current Isub increases, there is a fear that deterioration due to hot carriers or the like occurs.

On the other hand, in the first exemplary embodiment, the plurality of types of threshold voltages Vt are realized without increasing the impurity concentrations of the channel regions 1a, 1b, and 1c. Therefore, it is not necessary to set the impurity concentration of the channel region 1a of the MIS transistor (HVT) having a high threshold voltage to a high level, and hence the substrate current Isub may be suppressed even when the threshold voltage Vt is high (see the first exemplary embodiment of FIG. 6). As a result, a leakage current (including the sub-threshold leakage current and the substrate leakage current) may be reduced. Accordingly, the deterioration due to hot carriers may be improved.

Hereinabove, the case of applying the present invention to the NMOS transistors is exemplified. However, the present invention may similarly be applied to PMOS transistors as in the case of the NMOS transistors if a value of the threshold voltage is considered as an absolute value.

In the first exemplary embodiment, the antenna ratio (via area A/gate area R) is changed, to thereby realize the plurality of types of threshold voltages. Therefore, it is unnecessary to change the impurity concentrations of the channel regions 1a, 1b, and 1c of the MIS transistors, which eliminates the need to increase the number of photoresists and the number of steps of ion implantation. Accordingly, the manufacturing cost of the semiconductor device may be reduced.

Further, the antenna ratio may be set correspondingly to a layout pattern, and the interconnect vias and the electric charge capturing vias may be formed simultaneously. Therefore, the manufacturing steps may not be increased due to the formation of the electric charge capturing vias.

Still further, the threshold voltages are controlled without changing the impurity concentrations of the channel regions 1a, 1b, and 1c, and hence the leakage current including the substrate current and the sub-threshold leakage current may be reduced even when the threshold voltages are set to high values. As a result, the deterioration due to hot carriers may be alleviated.

The present invention may be applied to overall complementary metal oxide semiconductor (CMOS) products, and more particularly, to a microcomputer having a rewritable flash memory mounted therein.

Although the invention has been described above in connection with the exemplary embodiment thereof, it will be appreciated by those skilled in the art that the exemplary embodiment is provided solely for illustrating the invention, and should not be relied upon to construe the appended claims in a limiting sense.

Further, it is noted that, notwithstanding any claim amendments made hereafter, applicant's intent is to encompass equivalents all claim elements, even if amended later during prosecution.

What is claimed is:

1. A semiconductor device, comprising a plurality of metal insulator semiconductor (MIS) transistors,
the plurality of MIS transistors each including:
a gate electrode formed above a channel region of a semiconductor substrate via a gate insulating film; and
source/drain regions formed on both sides of the channel region,
the gate electrode being electrically connected to an interconnect via a first plug,
the interconnect having a plurality of vias formed thereon,
wherein the plurality of MIS transistors have threshold voltages different from one another due to variations in quantities of electric charges trapped by the gate insulating films respectively corresponding to the plurality of MIS transistors.

2. The semiconductor device according to claim 1, wherein the quantities of the electric charges trapped by the gate insulating films respectively corresponding to the plurality of MIS transistors are different from one another according to antenna ratios that are each based on a ratio of an area of the corresponding plurality of vias to an area of the corresponding gate electrode.

3. The semiconductor device according to claim 2, wherein each of the antenna ratios is adjusted by changing one of a number of the plurality of vias and the area of the plurality of vias, with respect to the area of the gate electrode.

4. The semiconductor device according to claim 1, wherein the plurality of MIS transistors have the same conductivity type.

5. The semiconductor device according to claim 1, wherein the channel regions of the plurality of MIS transistors have the same impurity concentration.

6. The semiconductor device according to claim 1, wherein:
the plurality of vias include a first via which is connected to an interconnect formed in an upper layer; and
the plurality of vias include a second via which avoids connection to the interconnect formed in the upper layer.

7. The semiconductor device according to claim 1, wherein the interconnect corresponding to a MIS transistor having a lowest threshold voltage of the plurality of MIS transistors is diode-connected to the semiconductor substrate via a second plug.

8. The semiconductor device according to claim 1, wherein the gate insulating film traps the electric charges which have been generated during one of formation of the plurality of vias and formation of prepared holes for the plurality of vias.
